(19) United States
(12) Patent Application Publication
(10) Pub. No.: US 2025/0185209 A1
(43) Pub. Date: Jun. 5, 2025

(54) Methods and Systems for Hybrid Liquid Cooled Data Center Management

(71) Applicant: Seguente, Inc., Melbourne, FL (US)

(72) Inventors: John Kim, Orlando, FL (US); Ryan Enright, Berkeley Heights, NJ (US); Raffaele Luca Amalfi, Melbourne, FL (US)

(21) Appl. No.: 18/962,015

(22) Filed: Nov. 27, 2024

Related U.S. Application Data
(60) Provisional application No. 63/605,153, filed on Dec. 1, 2023.

(51) Int. Cl. H05K 7/20

(52) U.S. Cl. CPC H05K 7/20272; H05K 7/2079; H05K 7/20836

(57) ABSTRACT

Methods and systems for collecting and analysing telemetry data from liquid cooled IT (Information Technology) devices and surrounding infrastructure that supports the IT devices. Data streams from highly heterogeneous data sources from multiple locations throughout a data center hosting liquid cooled IT devices provide deep insights to improve energy efficiency.

### CROSS REFERENCE TO RELATED APPLICATIONS

This application, which claims the benefit of priority to U.S. Provisional Patent Application Ser. No. 63/605,153 filed Dec. 1, 2023, the entire disclosure of which is incorporated by reference in its' entirety.

### FIELD OF INVENTION

This invention relates to methods and systems for collecting and analysing telemetry data from liquid cooled IT (Information Technology) devices and surrounding infrastructure that supports those devices. Data streams from highly heterogeneous data sources from multiple locations throughout a data center hosting liquid cooled devices enable data canter operators to improve the overall energy efficiency.

### BACKGROUND AND PRIOR ART

Data centers are at the center of modern digital infrastructure, serving as the backbone of the digital society. Data centers store, process, and deliver an ever more increasing demand of data that powers our digital activities.

However, rising energy cost and environmental concerns, coupled with stringent regulations are pushing data center operators to become more energy efficient. In response to these pressures, the data center industry is continuously seeking novel technologies and practices to achieve sustainability goals, while continuing to expand to meet the market demand.

While it is imperative for energy efficiency in data centers, unfortunately, highly dynamic nature of data center environment makes the problem multifaceted. Data centers take a wide range of workloads, with varying level of computational demands that dynamically change over time. As a result, data center operators constantly struggle to apply dynamic adjustments to prevent hardware underutilization or overutilization. Likewise, data center operators continuously attempt to prevent cooling infrastructure from overcooling or undercooling the IT equipment.

In addition, among many other reasons, highly diverse IT (Information Technology) hardware and cooling infrastructure makes management and overall optimization extremely challenging. Modern data centers use various hardware components (i.e., servers, switches, routers, etc.) and facility infrastructure (i.e., air handling units, power systems, etc.) each with its own power characteristics, energy efficiency levels, control software and data transfer protocols.

There are numerous prior arts within the subject matter. However, those previous disclosures do not teach or fairly suggest how to implement data collection and analysis methods and systems, using computer programs, to improve energy efficiency of data centers or any other IT sites, hosting a combination of air-cooled and liquid-cooled devices.

U.S. Pat. No. 9,250,962 to Brech et al., which is incorporated by reference, discloses techniques for scheduling received computational tasks in a data center in a manner that accounts for operating costs. The method attempts to optimize the operational cost by means of a computer program that can determine cost-saving methods for scheduling the task based on a job completion constraint.

However, the prior art does not teach or fairly suggest how such system may be implemented to improve the energy efficiency.

U.S. Pat. No. 9,720,738 patent to Anghel et al., which is incorporated by reference, discloses an automated data center scheduling of applications supported by machine learning techniques. A computer-implemented method receives computational tasks along with a set of task parameters specifying characteristics of the tasks to be performed. The parameters are then analyzed to determine the mapping of computational tasks to computing entities.

This disclosure generally teaches how computational tasks can be mapped onto computing entities, but does not teach or fairly suggest how high data center energy efficiency can be achieved through improved resource allocation.

U.S. Pat. No. 10,034,417 to Billet et al., which is incorporated by reference, discloses a simulation-based cooling optimization method that provides real-time cooling set points in a data center. Data center cooling operation takes a significant portion of the overall energy consumption. Therefore, data center operators need to adjust and allocate the right level of cooling across the data center space. The disclosure generally teaches how to use layout data including rack power and airflow to run computational simulation to determine optimal cooling set point. As modern data centers are switching over to liquid-cooling based thermal management solutions, this disclosure does not teach or fairly suggest how to achieve high energy efficiency in liquid-cooled data center.

U.S. Pat. No. 10,447,546 to Guo et al., which is incorporated by reference, discloses methods and apparatus for resource data visualization from plurality of storage, compute, and network resources from software defined data center, where elements of the infrastructure (e.g., networking, storage, compute) are virtualized and delivered to tenants of the data center as services. This disclosure further teaches customized visualization into one or more dashboards of a graphical user interface as monitoring and management tools.

This disclosure does not teach or fairly suggest how infrastructure/cooling facility resources can be further integrated into the visualization tool to further provide operational insights for data center operators.

U.S. Pat. No. 10,558,768 to Weber et al., which is incorporated by reference, discloses a method to calculate expected peak power draw of computing devices. The disclosure utilizes a computer simulation to compute potential for power and energy savings in data center. The disclosure generally teaches the use of model-based power monitoring techniques for power provisioning in real production systems at the scale of data center workloads.

However, the disclosure does not teach or fairly suggest how the disclosed method can be applied to provision a data center hosting computing devices cooled by liquid coolant.

U.S. Pat. No. 10,642,299 to Ewing et al., which is incorporated by reference, discloses systems and methods of power distribution, management, and monitoring in data centers. In particular, the disclosure teaches how to monitor and manage power distribution units (PDU) from which energy-related information can be obtained.

The disclosure does not teach or fairly suggest how the data from PDU can be further utilized for improving the overall data center energy efficiency.

U.S. Pat. No. 10,831,253 to Ghose, which is incorporated by reference, discloses a system and method of scheduling tasks for improving efficiency at the server level. The method teaches how to utilize a scheduling scheme to control signals for cooling system and control signals for server-local energy capping and management.

However, the disclosure does not teach or fairly suggest how the scheme can be applied at the data center scale to achieve the overall energy efficiency of a data center.

U.S. Pat. No. 11,423,200 to Pei et al., which is incorporated by reference, discloses systems and methods to optimize the energy efficiency of pump machine unit using digital twins and machine learning models by determining the optimized operation regulation system.

While the disclosure teaches the use of machine learning and digital twin to improve energy efficiency of a physical device, the disclosure does not teach or fairly suggest how the disclosed systems and methods can be applied to improve data center energy efficiency.

Thus, the need exists for solutions to the problems with the prior art.

### SUMMARY OF THE INVENTION

A primary objective of the invention is to provide methods and systems for collecting and analyzing telemetry data from liquid cooled IT (Information Technology) devices and surrounding infrastructure that supports the IT devices, wherein data streams throughout a data center provide feedback to improve energy efficiency.

Thermal management solution that uses liquid coolant to maintain a stable operating temperature is getting market traction to tackle the most challenging thermal outputs from high density servers. This transition has several potential advantages in improving the overall data center energy efficiency.

First and foremost, the liquid cooling can offload the reliance on air conditioning systems as high heat generating components (i.e., CPU (Central Processing Unit) and GPU (Graphical Processing Unit) will be cooled by liquid. In addition, compared to air-based thermal management solutions, the heat captured in liquid can be easily directed to the final heat rejection site and can be precisely quantified.

Through careful data collection and analyses, data center operators many have potential to improve the overall data center energy efficiency. This invention teaches how systems and methods can help data centers achieve optimal energy efficiency despite having highly heterogeneous IT (Information Technology) hardware and cooling infrastructure that make management and overall optimization extremely challenging.

Implementation of methods and systems to improve energy efficiency may include one or more IT devices with that are cooled by liquid-phase coolant that circulates in and out of IT equipment. A single coolant loop may transport heat from IT equipment to a heat rejection unit (HRU) though one or more heat exchangers that can form cascading circulation loops to transport heat from the origin (i.e., IT equipment) to the final heat rejection site.

In one aspect, liquid cooling infrastructure comprises a complex fluid network with at least one parallel liquid flow path connecting at least one heat generating electronic component to at least one heat rejection unit. Complex fluidic network connecting multiple heat generating electronic components and heat sinks is equipped with at least one pump and at least one valve that can collectively adjust the overall heat flow pattern.

In one aspect, the coefficient of performance (COP) of each heat rejection equipment is determined at a given flow distribution state across the fluidic network. A heat metering system calculates the total thermal energy being rejected by a heat rejection unit.

Electrical power consumption of a heat rejection unit is directly measured from electrical power meter. The COP is calculated by taking the ratio of the thermal energy removed divided by the electrical energy input needed to operate the heat rejection unit.

In one aspect, a computer program constantly monitors the COP of heat rejection units within the system. A computer system is provided with a fluidic topology that determines how the combined COP should be calculated based on individual COP, depending on the fluidic network topology.

In one aspect, one or more sensors can measure flow rate and temperature of the circulating coolant that is directly or indirectly in contact with heat generating components of IT devices. Telemetry data from the communicatively connected sensors may be readily available through a network via a protocol, including but not limited to SNMP, IPMI, Redfish, REST API, or combination thereof.

In one aspect, the cooling infrastructure can involve heat exchange process across one or more heat exchangers that can involve single phase (liquid) or two-phase (liquid/gas mixture) coolant to promote effective heat transfer. A pipe circulating single phase (liquid or gas) or two-phase (liquid/gas mixture) coolant may have one or more diverging and/or converging branches to form a fluid pipe network to connect one or more heat generating electronic components to one or more heat rejection locations.

In another aspect, one or more power distribution unit (PDU) connected to a network may provide power usage data by IT devices or networking devices. In another aspect, one or more IT devices connected to a network can provide power usage, CPU/GPU usage, temperature of several components, which can include one or more memory device, storage device, networking device, or expansion cards.

In another aspect, one or more in-rack, room-level or facility scale air handling units, evaporative chiller, dry cooler, air-cooled chiller, liquid-cooled chiller, direct expansion (DX) system may have sensors that report coolant flow rate, air/liquid temperature, fan speed, or pump speed. The sensors are communicatively connected and readily accessible.

In another aspect, one or more processing units running computer codes comprising a graphical user interface or command-line interface (CLI), one or more agents for collecting data from multiple data sources, one or more databases located in one or more data storage media. A user interacts with GUI or CLI to provide user inputs to configure desired system states.

In another aspect, a method of applying machine learning based models for evaluating current operational state and ideal state, using a combination of input data, including data streams from one or more IT devices, networking devices, network-enabled flow meters and temperature sensors near heat exchangers, power distribution units. Ideal state can be defined by data center operators based on objectives, which can be based on energy efficiency, hardware utilization, uptime, heat capture efficiency, or carbon offset.

A method of identifying ideal operational parameters can include reinforcement learning. Operational parameters can include, but not limited to configuring workload balancing, modulating pump or fan speeds of heat rejection units, valve positions, or combination thereof. The operational parameters can also include temperature setpoints of the heat rejection unit. The operational parameters can also include proportional valve control to modulate flow rate or pressure drop of coolant fluid interacting with IT devices. The operational parameters can also include fan speed of supplementary air-cooling fans inside IT devices or operational parameters of computer room air conditioning (CRAC) units or a computer room air handler (CRAH).

In another aspect, all input and output results can be displayed through an interactive user interface that can be customized by the data center operator. The graphical user interface (GUI) can include one or more digital representations of the data center to promote intuitive understanding of the operational status of the data center.

In another aspect, a computer program constantly or periodically from time to time compares ideal operational state and actual operational state to determine anomalous state. Anomalous state can be corrected by adjusting operational parameters, or issuing warnings to which operators can respond for further actions.

In another aspect, all input and output data can be accessed by an application programming interface (API).

In another aspect, a method for proactively detecting and addressing abnormal system behaviors in complex systems comprising IT devices, network devices, fluid networks, heat exchangers, and heat rejection units. The method employs an anomaly detection algorithm to identify unusual patterns or behaviors that can indicate a hardware component is malfunctioning or failing.

In another aspect, a method for mitigating the effects of anomalous behavior in complex systems, comprising a series of automated responses to ensure system integrity and minimize downtime. In the event of an anomaly detection alert, the method executes a set of instructions that redirects incoming network traffic away from affected IT devices, preventing further corruption or damage.

Additionally, important data stored on compromised network-attached storage devices is transferred to a secure location, ensuring business continuity and minimizing data loss. If necessary, the method also initiates a controlled shutdown sequence for affected IT systems, gradually powering them down to prevent physical damage or harm. This proactive approach enables swift recovery from anomalies, reduces the risk of cascading failures, and minimizes the potential for data corruption or loss.

In another aspect, a method for generating accurate sustainability reports for multi-tenant cloud infrastructure, enabling data center operators to track and optimize energy efficiency. The method computes the power consumption of each individual tenant in proportion to their actual usage patterns, taking into account factors such as processor, memory, and network utilization.

This calculation is then normalized against the total IT infrastructure power consumption, providing a granular view of each tenant's energy footprint.

In addition, the method also considers cooling power consumption, which is calculated based on processor utilization for each individual tenant. By combining these two metrics, the method generates a partial Power Usage Effectiveness (PUE) score for each tenant, providing valuable insights into their specific energy usage and waste. This detailed reporting enables data center operators to identify areas for improvement, optimize energy efficiency, and make informed decisions about infrastructure design and operations, ultimately contributing to a more sustainable and environmentally responsible cloud computing ecosystem.

In another aspect, a method for empowering end-users to take control of their IT infrastructure's energy efficiency and carbon footprint, promoting sustainable computing practices. The method monitors key performance indicators (KPIs) in real-time, including floating point operations per second (FLOPS), input power consumption, and cooling power consumption. This data is then made available to end-users, enabling them to track the energy efficiency and environmental impact of their computing resources.

With this transparency, end-users are incentivized to modify their operational behavior to improve sustainability metrics, such as reducing energy waste or optimizing resource utilization. The method also allows end-users to optimize their computing resource utilization to achieve maximum FLOPS per unit of CO2 emissions, thereby minimizing their environmental footprint and improving overall sustainability. By providing actionable insights and empowering end-users to make data-driven decisions, the method promotes a culture of sustainability and reduces the environmental impact of IT operations.

In another aspect, A system for tracking and reporting IT infrastructure sustainability metrics, providing users with actionable insights to reduce their environmental footprint. The system includes a baseline calculation model that analyzes historical usage patterns to establish a baseline carbon emission level for the IT infrastructure. This data is then combined with actual carbon emission data collected in real-time from sensors and meters monitoring power consumption, cooling usage, and other relevant environmental metrics.

Additionally, the system incorporates carbon offset data obtained from a reliable source, such as a certified carbon offset program or organization that complies with international standards for greenhouse gas accounting. This comprehensive dataset is stored on user-accessible storage media with an immutable database, ensuring the integrity and accuracy of sustainability metrics.

To maintain transparency and accountability, the system features a secure logging mechanism to track changes and maintain audit trails. Regularly executed computer scripts or user-initiated requests generate reports detailing energy efficiency metrics, carbon footprint, and potential carbon credits. These reports provide valuable insights, including actual carbon emission data, baseline carbon emission, carbon offset data, recommendations for improving sustainability based on identified areas of opportunity.

By providing a comprehensive picture of IT infrastructure sustainability, the system empowers users to make informed decisions about energy efficiency, resource allocation, and environmental responsibility.

Further objects and advantages of this invention will be apparent from the following detailed description of the presently preferred embodiments which are illustrated schematically in the accompanying drawings.

### BRIEF DESCRIPTION OF THE FIGURES

The drawing figures depict one or more implementations in accord with the present concepts, by way of example only, not by way of limitations. In the figures, like reference numerals refer to the same or similar elements.

FIG. 1 shows a flowchart example of an overall energy flow from heat generating electronic component to final heat rejection locations. A complex fluid network can transfer heat from the source to the final heat rejection site through heat exchangers and cascaded coolant loops. High energy efficiency can be achieved by optimizing the flow network throughout a data center by adjusting operational parameters based on telemetry data supplemented with computational models. Computer code running inside a computing device analyses the data and provide operational parameters that can be updated to improve energy efficiency of a data center. A user interface helps data center operators understand highly complex operational status.

FIG. 2 shows a schematic example of a data canter with liquid cooled IT devices. Heat and mass transfer through complex pipe network can be optimized using computer models with telemetry data as input data.

### DESCRIPTION OF THE PREFERRED EMBODIMENTS

Before explaining the disclosed embodiments of the present invention in detail it is to be understood that the invention is not limited in its applications to the details of the particular arrangements shown since the invention is capable of other embodiments. Also, the terminology used herein is for the purpose of description and not of limitation. In the Summary above and in the Detailed Description of Preferred Embodiments and in the accompanying drawings, reference is made to particular features (including method steps) of the invention.

It is to be understood that the disclosure of the invention in this specification does not include all possible combinations of such particular features. For example, where a particular feature is disclosed in the context of a particular aspect or embodiment of the invention, that feature can also be used, to the extent possible, in combination with and/or in the context of other particular aspects and embodiments of the invention, and in the invention generally.

In this section, some embodiments of the invention will be described more fully with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will convey the scope of the invention to those skilled in the art. Like numbers refer to like elements throughout, and prime notation is used to indicate similar elements in alternative embodiments.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise specifically noted, articles depicted in the drawings are not necessarily drawn to scale.

### List of Abbreviations

API Application programming interface
BACNET building automation and control network
BMC baseboard management controller
CDU coolant distribution unit
CLI command-line interface
COP coefficient of performance
CPU central processing unit
CRAC computer room air conditioning
CRAH computer room air handler
DX direct expansion
FLOPS floating point operations per second
GPU graphical processing unit
HRU heat rejection unit
IPMI Intelligent platform management interface
IT Information Technology
KPI key performance indicators
PUE partial Power Usage Effectiveness
PDU Power distribution unit
SNMP simple network management protocol
WUE water usage effectiveness

A list of the referenced components will now be described.
100 load balancer
102 fluid pipe network
103 computing device
104 computer software
105 heat generating electronic component
106 first heat exchanger (cold plate or evaporator)
107 first coolant loop
108 first heat rejection unit (air-cooled chillers, rack mount coolant distribution units (CDU), water-cooled chillers, direct expansion units)
109 second heat exchanger (cold plate or evaporator)
110 second coolant loop
111 second heat rejection unit (air-handling unit, evaporative cooler, or dry cooler)
112 temperature sensor
113 flow rate sensor
114 power usage sensor
115 pump
116 valve
200 typical data canter
201 multiple computer racks
202 networking device
203 power distribution unit
204 servers
205 CRAC (Computer room air conditioning) unit
206 space above raised floor
207 in-rack CDU (coolant distribution unit)
208 in-row CDU (coolant distribution unit)
209 heat exchanger (cold plate or evaporator)
210 facility coolant loop
211 valve
212 heat rejection unit (air-handling unit, evaporative cooler, or dry cooler)
213 facility loop
214 server rooms
215 pipe branch
216 Pump

The assignee and inventors have related patent applications in this field. See for example, U.S. patent application Ser. No. 18/209,752 filed Jun. 14, 2023, which claims the benefit of priority to U.S. Provisional Patent Application Ser. No. 63/353,224 filed Jun. 17, 2022; U.S. patent application Ser. No. 18/209,752 filed Jun. 14, 2023 is a Continuation-In-Part of U.S. patent application Ser. No. 18/198,522 filed May 17, 2023 which claims the benefit of priority to U.S. Provisional Application Ser. No. 63/344,291 filed May 20, 2022. The entire disclosure of each of the applications listed in this paragraph are incorporated herein by specific reference thereto.

### Hybrid Liquid Cooled Data Center Management System

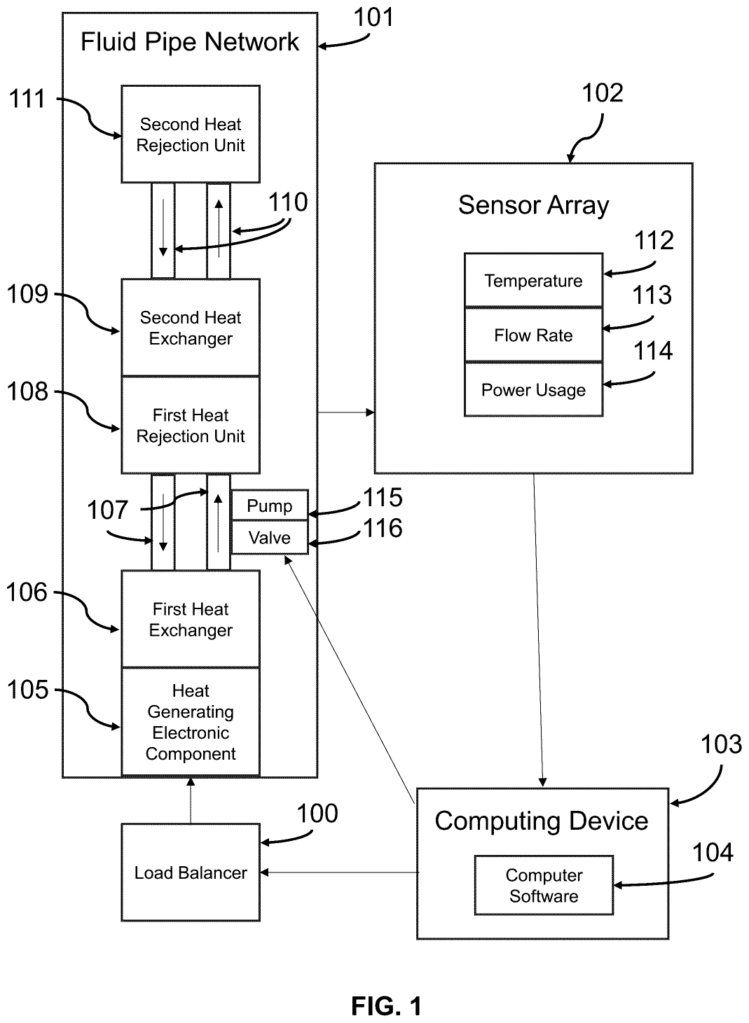

FIG. 1 shows a flowchart example of an overall energy flow from heat source to final heat rejection locations. A complex fluid network can transfer heat from the source to the final heat rejection site through heat exchangers and cascaded coolant loops. High energy efficiency can be achieved by optimizing the flow network throughout a data center by adjusting operational parameters based on telemetry data supplemented with computational models.

With reference to FIG. 1, the present invention contemplates a data capture and management system. In some embodiments, the data capture and management system comprises a load balancer 100, a fluid pipe network 101, a sensor array 102, and a computing device 103 executing computer software 104.

In some embodiments, the fluid pipe network 101 includes at least one heat generating electronic component 105, at least one first heat exchanger 106, at least one first coolant loop 107 containing coolant, at least one heat rejection unit 108, at least one second heat exchanger 109, at least one second coolant loop 110 containing coolant, and at least one second heat rejection unit 111. In some embodiments, the sensor array 102 is coupled to the fluid pipe network 101 includes one or more sensors, including, for example, a temperature sensor 112, a flow rate sensor 113, and a power usage sensor 114.

The heat generating electronic component 105 can be, for example, one or more central processing units or one or more graphics processing units. The first heat exchanger 106 and the second heat exchanger 109 can be, for example, one or more cold plates or one or more evaporators. The coolant of the first coolant loop 107 and second coolant loop 110 can be, for example liquid-to-liquid, liquid-to-gas, liquid and gas mixture to liquid and gas mixture, or liquid and gas mixture to gas. The first heat rejection unit 108 can be, but not limited to, an air-cooled chiller, a rack-mount CDU, a water-cooled chiller, a direct expansion unit, or a combination thereof. The second heat rejection unit 111 can be, but not limited to, an air handling unit, an evaporative cooler, a dry cooler, or a combination thereof.

In some embodiments, the load balancer 100 is configured to receive data from the computer software 104 and send data to the heat generating electronic component 105. The heat generating electronic component 105 is configured to receive data from the load balancer 100 and transfer heat to the first heat exchanger 106.

The first heat exchanger 106 is configured to receive heat from the heat generating electronic component 101 and to transmit heat to the first coolant loop 107. The first coolant loop 107 is configured to receive heat from the first heat exchanger 106 and transmit heat to the first heat rejection unit 109.

The first heat rejection unit 108 is configured to receive heat from the first coolant loop 107 and to transmit heat to the second heat exchanger 109.

The second heat exchanger 109 is configured to receive heat from the first heat rejection 108 and transmit heat to the second coolant loop 110.

The second coolant loop 110 is configured to receive heat from the second heat exchanger 109 and transmit heat to the second heat rejection unit 111. The second heat rejection unit 111 is configured to receive heat from the second coolant loop 110 and transmit heat out of the system to ambient air.

In some embodiments, at least one pump 115 and at least one valve 116 are coupled to the fluid pipe network 101 such that pump 115 and valve 116 are configured collectively adjust the overall heat flow pattern of the fluid pipe network 101.

The fluid pipe network 101 is configured to send data to the sensory array 102. The sensory array 102 is configured to receive data from the fluid pipe network 101 and send data to the computer software 104.

The computing device 103 executes computer software 104 which is configured to receive data from the sensor array 102. The computing software 104 analyzes that data, presents the data visually to the user in human-readable format, and sends that data to the load balancer 100.

In some embodiments, the computer software 104 is configured to send data to the one or more pumps 115 and the one or more valves 116 of the fluid pipe network 101. In some embodiments the computer software 104 is configured to modulate the speed of the pump 115 of the fluid pipe network 101. In some embodiments, the computer software 104 is configured to set valve 116 positions.

As noted, the sensor array 102 can comprise one or more sensors that are configured to detect the operational characteristics of the fluid pipe network 101. A temperature sensor 112, for example, such as but not limited to an

Omega resistance temperature detectors is used to measure the temperature of the coolant contained in coolant loops 107 and 109.

A flow rate sensor 113, for example, such as but not limited to a Belimo thermal energy meter, is used to measure the flow rate of the coolant within coolant loops 107 and 110.

A power usage sensor 114, for example, such as but not limited to a nVent enLOGIC metered power distribution unit or a Schneider Electric power meter, is used to measure the power usage of pump 115.

A computing device 103, for example a desktop computer is used to execute the computer software 104.

The computer software 104, for example the Applicant's own custom-engineered data center management software, is used to visually present data to the user, for example in a graphical format, and in some embodiments, send data to the load balancer 100. The load balancer 100, for example, such as but not limited to a Kubernetes load balancer is used to send data to the heat generating component 105.

### Hybrid Liquid Cooled Data Center Management Method

The sensor array 102 in real-time monitors and captures the data for temperature, flow rate, and power usage detected by the one or more sensors of the sensor array 102. For example, if the temperature sensor 112 detects a temperature that is over a maximum temperature threshold, this may indicate that too much data is being sent to the heat generating component 105.

Similarly, unexpected drops in flow rate detected by the flow rate sensor 113 may indicate a clog in the first coolant loop 107 or second coolant loop 109. Further, unexpected spikes in power usage detected by the power usage sensor 114 may indicate a component of the fluid pipe network 101 is performing in a suboptimal fashion.

Once the load balancer 100 sends data to the heat generating electronic component 105, the heat generating electronic component 105 begins to generate heat, then heat begins to travel through the fluid pipe network 101. The heat of the heat generating electronic component 105 is transferred to the first heat exchanger 106.

The heat from the first heat exchanger 106 is transferred via the first coolant loop 107 to the first heat rejection unit 108. The heat of the first heat rejection unit 108 is transferred to the second heat exchanger 109. The heat of the second heat exchanger 109 is transferred via the second coolant loop 110 to the second heat rejection unit 111. The heat of the second heat rejection unit is transferred to the ambient air.

As heat travels through the fluid pipe network 101, the sensor array 102 measures the temperature, flow rate, and power usage of the fluid pipe network 101. The data gathered by the sensor array 102 is sent to the computing device 103 that is executing a computer software 104.

The computer software 104 analyzes and displays the data to a user in a human readable format. The user may then use pump 115 and valve 116 to collectively change the heat flow pattern of the fluid pipe network 101 based on the human readable data.

In some embodiments, the computer software 104 is configured to send data to the one or more pumps 115 and the one or more valves 116 of the fluid pipe network 101. In some embodiments the computer software 104 is configured to modulate the speed of the pump 115. In some embodiments, the computer software 104 is configured to set valve 116 positions.

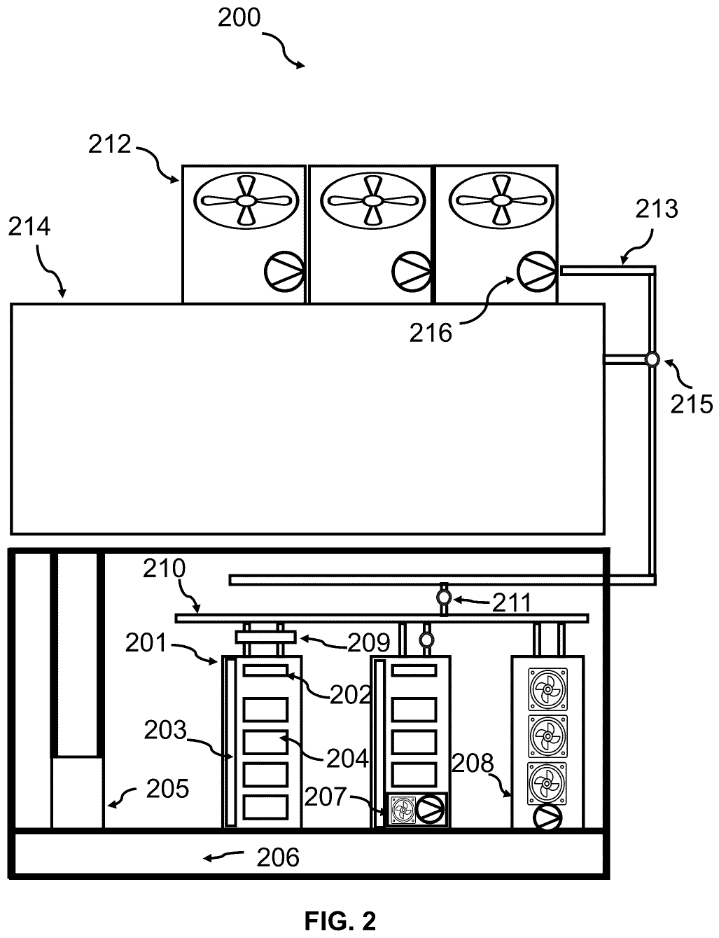

FIG. 2 shows a schematic example of a data canter with liquid cooled IT devices. Heat and mass transfer through pipe network can be optimized using computer models with telemetry data as input data.

FIG. 2 shows a fluid network and components of a typical data center 200. A typical data center 200 hosts multiple computer racks 201, comprising networking device 202, power distribution unit 203, and servers 204. Cool air is introduced to the computer room via CRAC (computer room air conditioning unit) 205 through space below raised floor 206.

Along with supplementary cool air, liquid coolant can be implemented to remove heat from heat generating devices. An in-rack CDU 207 or in-row CDU 208 can reject heat to air. An in-rack CDU 207, can include, but is not limited to ColdWare passive coolant distribution (pCDU) or a standard 4 rack unit (4 U) water coolant distribution unit cud integrated into a rack, transferring up to about 200 kW of thermal energy. An in-row CDU 208, can include, but is not limited to a rack-sized floor standing equipment from nVent, Vertiv, Schneider Electric, or Stulz.

Circulating coolant can remove heat to facility heat rejection unit 212, such as but not limited to an air-handling unit, evaporative cooler, or dry cooler.

A heat exchanger 209 transfers heat from heat source to facility coolant loop 210. Coolant flow path can be modulated by controlling a valve 211 to distribute and adjust the amount of heat being transferred to each coolant loop. Heat exchanger 209 can include, but is not limited to a brazed plate heat exchanger or a shell and tube heat exchanger. Valve 211 can include but is not limited to a variety of valve products from Belimo, such as an energy valve, pressure independent control valve, zone valve, characterized control valve, ball valve, butterfly valve, globe valve, or a combination thereof.

Heat is finally removed to the outside air via heat rejection unit 212 via facility loop 213.

A facility coolant loop 210 circulates water and transfer heat from heat source to in-rack CDU 207 or in-row CDU 208.

A facility coolant loop can be further extended 213 to make a fluidic connection with a heat rejection unit 212 that is removing heat to the outside air. The extended facility coolant loop 213 can be fluidically isolated with a coolant loop 210 using a valve 211 to control the amount of flow circulation between two loops. Facility coolant loop can include, but is not limited to metal pipes or plastic pipes circulating water, water glycol mixture or refrigerant. Extended coolant loop 213 can include, but is not limited to metal pipes or plastic pipes circulating water, water glycol mixture or refrigerant.

An extended facility coolant loop 213 can transfer heat from plurality of server rooms 214. A pipe branch 215 facilitate distribution of coolant to plurality of locations within the facility. A pipe branch can include, but is not limited to a Wye-branch, Tee-branch, three way valve or proportional valve, or a combination thereof.

The term “about”/“approximately”/“approximate” can be +/−10% of the amount referenced. Additionally, preferred amounts and ranges can include the amounts and ranges referenced without the prefix of being approximately.

Although specific advantages have been enumerated above, various embodiments may include some, none, or all of the enumerated advantages.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

While the invention has been described, disclosed, illustrated and shown in various terms of certain embodiments or modifications which it has presumed in practice, the scope of the invention is not intended to be, nor should it be deemed to be, limited thereby and such other modifications or embodiments as may be suggested by the teachings herein are particularly reserved especially as they fall within the breadth and scope of the claims here appended.

We claim:

1. A system for hybrid liquid cooled data center management of a facility, comprising:
at least one load balancer, at least one fluid pipe network, at least one sensor array, and a computing device executing computer software;
the fluid pipe network comprising one or more heat generating electronic components, first heat exchangers, first coolant loops containing a coolant, first heat rejection units, second heat exchangers, second coolant loops, and second heat rejection units;
the at least one load balancer configured to receive data from the computer software and send data to the heat generating electronic component;
the at least one heat generating electronic component configured to receive data from the load balancer and transfer heat to the first heat exchanger;
the first heat exchanger configured to receive heat from the heat generating electronic component and to transmit heat to the first coolant loop;
the first coolant loop configured to receive heat from the first heat exchanger and transmit heat to the first heat rejection unit;
the first heat rejection unit configured to receive heat from the first coolant loop and to transmit heat to the second heat exchanger;
the second heat exchanger configured to receive heat from the first heat rejection unit and transmit heat to the second coolant loop;
the second coolant loop configured to receive heat from the second heat exchanger and transmit heat to the second heat rejection unit;
the second heat rejection unit configured to receive heat from the second coolant loop and transmit heat out of the system to ambient air;
the sensor array comprising one or more sensors configured to detect one or more operational conditions of the fluid pipe network;
the sensor array in communication with the computing device executing computing software; and
the computing device executing computer software, the computer software configured to present sensor data received from the one or more sensors of the sensor array to enable a user to read operating conditions of the fluid pipe network detected by the one or more sensors of the sensory array.

2. The system of claim 1, wherein the sensors of the sensor array includes one or more of a temperature sensor, a flow rate sensor, and a power usage sensor.

3. The system of claim 1, wherein the fluid pipe network further comprises one or more pumps and one or more valves.

4. The system of claim 3, wherein the computer software is configured to send data to the one or more pumps and the one or more valves of the fluid pipe network.

5. The system of claim 4, wherein the computer software is configured to modulate speed of the pump of the fluid pipe network.

6. The system of claim 4, wherein the computer software is configured to set valve positions.

7. The system of claim 3, wherein the pump and valve are configured collectively adjust heat flow pattern of the fluid pipe network.

8. The system of claim 1, wherein the heat generating electronic components include one or more central processing units, one or more graphics processing unit, or a combination thereof.

9. The system of claim 1, wherein the coolant contained in the first and second coolant loops comprises liquid-to-liquid, liquid-to-gas, liquid and gas mixture to liquid and gas mixture, or liquid and gas mixture to gas.

10. The system of claim 1, wherein the sensor array continuously measures the operational conditions of the fluid pipe network.

11. A method for hybrid liquid cooled data center management of a facility, comprising:
providing a load balancer, a fluid pipe network, a sensor array, and a computing device, wherein the sensor array comprises one or more sensors configured to detect one or more operating conditions of the fluid pipe network, wherein the fluid pipe network comprises one or more heat generating electronic components, first heat exchangers, first coolant loops containing a coolant, first heat rejection units, second heat exchangers, second coolant loops, and second heat rejection units;
establishing a communications link between the sensor array and the computing device;
receiving, on the computing device, one or more signals corresponding to the one or more sensors; and
executing computer software on the computing device, the computer software displaying sensor data into a human readable format, the sensor data corresponding to the one or more operating conditions of the fluid pipe network.

12. The method of claim 11, wherein the sensors of the sensor array includes one or more of a temperature sensor, a flow rate sensor, and a power usage sensor.

13. The method of claim 11, wherein the fluid pipe network further comprises one or more pumps and one or more valves.

14. The method of claim 13, wherein the computer software is configured to send data to the one or more pumps and the one or more valves of the fluid pipe network.

15. The method of claim 14, wherein the computer software is configured to modulate speed of the pump of the fluid pipe network.

16. The method of claim 14, wherein the computer software is configured to set valve positions.

17. The method of claim 13, wherein the pump and valve are configured collectively adjust heat flow pattern of the fluid pipe network.

18. The method of claim 11, wherein the heat generating electronic components include one or more central processing units, one or more graphics processing unit, or a combination thereof.

19. The method of claim 11, wherein the coolant contained in the first and second coolant loops comprises liquid-to-liquid, liquid-to-gas, liquid and gas mixture to liquid and gas mixture, or liquid and gas mixture to gas.

20. The method of claim 11, wherein, wherein the sensor array continuously measures the operational conditions of the fluid pipe network.
